(19) United States
(12) Patent Application Publication
(10) Pub. No.: US 2015/0056370 A1
(43) Pub. Date: Feb. 26, 2015

(54) THIN FILM DEPOSITION APPARATUS AND THIN FILM DEPOSITION METHOD USING THE SAME

(71) Applicant: Samsung Display Co., Ltd., Yongin-City (KR)

(72) Inventor: Jae-Cheol Lee, Yongin-City (KR)

(73) Assignee: Samsung Display Co., Ltd., Yongin-City (KR)

(21) Appl. No.: 14/217,188

(22) Filed: Mar. 17, 2014

(30) Foreign Application Priority Data
Aug. 22, 2013 (KR) 10-2013-0099921

(51) Int. Cl. H01L 51/56

(52) U.S. Cl. CPC H01L 51/56
USPC 427/162; 118/721; 427/248.1

(57) ABSTRACT

A thin film deposition apparatus includes a mask in contact with a first surface of a substrate, a magnet plate above a second surface of the substrate and configured to pull the mask toward the first surface of the substrate, the second surface being an opposite surface to the first surface, and an insulating member between the magnet plate and the second surface of the substrate.

### CROSS-REFERENCE TO RELATED APPLICATION

This application claims priority to and the benefit of Korean Patent Application No. 10-2013-0099921, filed on Aug. 22, 2013 in the Korean Intellectual Property Office, the disclosure of which is incorporated herein in its entirety by reference.

### BACKGROUND

1. Field

One or more embodiments of the present invention relate to a thin film deposition apparatus that forms a thin film on a surface of an object by generating vapor of a deposition source, and more particularly, to a thin film deposition apparatus that forms a deposition pattern by using a mask and a thin film deposition method using the same.

2. Description of the Related Art

In general, an organic light-emitting apparatus includes a display unit having a structure in which an emission layer formed of an organic material is disposed between an anode and a cathode. When voltages are respectively applied to the anode and the cathode, holes injected from the anode and electrons injected from the cathode are recombined in the emission layer to generate excitons, and an image is displayed as light is emitted due to the transition of the excitons from an excited state to a ground state.

Because the emission characteristics of the emission layer of the display unit may be quickly degraded when the emission layer comes into contact with moisture, the emission layer may be covered with an encapsulation member in order to reduce or prevent this. Recently, research into a thin film encapsulation layer as the encapsulation member, to be used to manufacture a flexible organic light-emitting display apparatus, has been conducted.

### SUMMARY

One or more embodiments of the present invention include an improved thin film deposition apparatus that may effectively reduce or prevent the occurrence of local thick-film defects during a deposition process, and a thin film deposition method using the same.

Additional aspects and/or characteristics will be set forth in part in the description which follows and, in part, will be apparent from the description or may be learned by practice of the presented embodiments.

According to an embodiment of the present invention, a thin film deposition apparatus includes a mask in contact with a first surface of a substrate; a magnet plate above a second surface of the substrate and configured to pull the mask toward the first surface of the substrate, the second surface of the substrate being an opposite surface to the first surface; and an insulating member between the magnet plate and the second surface of the substrate.

The insulating member may include a fluororesin or polyether ether ketone.

The insulating member may cover an entire surface of the magnet plate that faces the second surface of the substrate or may cover a portion thereof.

The insulating member may have a grid shape.

The magnet plate may include a plurality of magnets surrounded by a filler.

The magnets in the magnet plate may be arranged as a grid.

The magnets in the magnet plate may be arranged in a repeating pattern.

According to another embodiment of the present invention, a method of depositing a thin film includes preparing a substrate in a chamber, a mask that is in contact with a first surface of the substrate, and a magnet plate on an insulating member that is on a second surface of the substrate opposite to the first surface; and operating a deposition source prepared in the chamber to form a thin film on the first surface of the substrate through the mask.

The thin film formed on the first surface of the substrate may include an organic layer for thin film encapsulation of an organic light-emitting display apparatus.

The insulating member may include a fluororesin or polyether ether ketone.

The insulating member may cover an entire surface of the magnet plate that faces the second surface of the substrate or may cover a portion thereof.

The insulating member may have a grid shape.

### BRIEF DESCRIPTION OF THE DRAWINGS

These and/or other aspects and characteristics will become apparent and more readily appreciated from the following description of the embodiments, taken in conjunction with the accompanying drawings in which:

FIG. 1 illustrates a structure of a thin film deposition apparatus according to an embodiment of the present invention;

FIG. 2A is an enlarged view illustrating a part of the thin film deposition apparatus illustrated in FIG. 1;

FIG. 2B illustrates a comparative example with respect to the thin film deposition apparatus illustrated in FIG. 2A; and

FIGS. 3A and 3B illustrate a structure of a thin film deposition apparatus according to another embodiment of the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. Expressions such as “at least one of,” when preceding a list of elements, modify the entire list of elements and do not modify the individual elements of the list. Further, the use of “may” when describing embodiments of the present invention refers to “one or more embodiments of the present invention.”

Hereinafter, example embodiments of the present invention will be described in detail with reference to the accompanying drawings.

Forming a thin film encapsulation layer of an organic light-emitting display apparatus is an example of thin film deposition. To form the thin film encapsulation layer, a mask is disposed on a substrate and a thin film is deposited to form the thin film encapsulation layer covering a display unit. In one example embodiment, a magnet plate may be installed on a surface of the substrate opposite to a surface of the substrate contacting the mask so the mask and the substrate may firmly contact (e.g., may closely contact or adhere to) each other. That is, because the mask is pulled toward the substrate by magnetic force of the magnet plate, the substrate and the mask are firmly in contact (e.g., in close contact) with each other.

Because a surface of the magnet plate generally has a roughness (e.g., a roughness amplitude) of about few pm, a state of partial point contact, in which only protruding portions of the surface of the magnet plate, due to the surface roughness, are directly in contact with the substrate, is formed and is visible when a contact surface between the magnet plate and the substrate is closely examined. That is, the protruding portions of the surface of the magnet plate, due to the surface roughness, are in contact with the substrate and other portions (e.g., recessed portions) of the surface of the magnet plate are not in contact with the substrate. As a result, the occurrence of local thick-film defects may be increased, in which a relatively thicker film is deposited on the portions of the substrate being in point contact with the magnet plate when a thin film is deposited. The reason for this is that, because the magnet plate is generally formed of a metallic material having relatively high thermal conductivity, a temperature of the substrate at the portions being in point contact with the magnet plate is relatively lower than that of the substrate at portions that are not in point contact with the magnet plate during the deposition. Then, a phenomenon (e.g., so-called “thermo-capillary convection effect”) occurs, in which a deposit in an unsolidified state (e.g., in a liquid phase or state) is accumulated at the portions of the substrate having a lower temperature, and thus, a thicker film is formed on the corresponding portions.

When this happens, visually identifiable circular stains may remain in the corresponding portions to eventually form defective products.

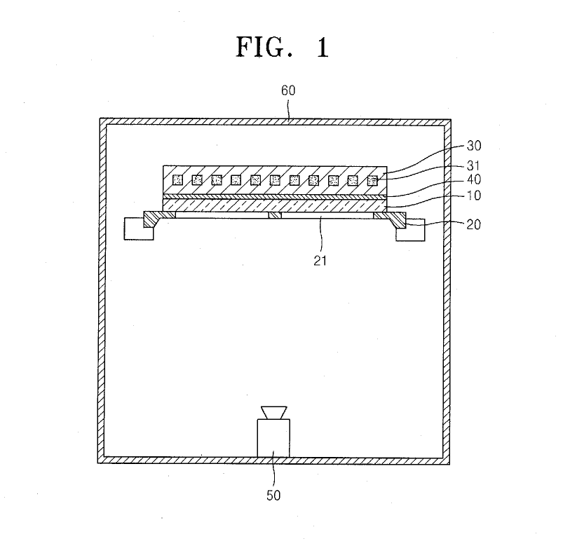

An embodiment of the present invention will now be described with reference to FIG. 1.

As illustrated in FIG. 1, the thin film deposition apparatus according to the present embodiment includes a mask 20 that is in contact (e.g., close contact or direct contact) with a first surface of a substrate 10 as a deposition target, and a magnet plate 30 disposed on a second surface of the substrate 10, which is an opposite surface to the first surface, and an insulating member 40 disposed between the magnet plate 30 and the second surface of the substrate 10. Reference numeral 50 denotes a deposition source configured to inject a deposition gas, and reference numeral 60 denotes a chamber.

Therefore, when the deposition source 50 injects the deposition gas in the chamber 60, a thin film having a pattern may be formed as the corresponding deposition gas is deposited on the substrate 10 by passing through openings 21 formed in the mask 20.

In this case, the magnet plate 30 pulls the mask 20 to be firmly in contact (e.g., in close contact) with the substrate 10 by magnetic force of magnets 31 that are in (e.g., embedded in) the magnet plate 30. Therefore, a deposition process may be performed in a state in which the mask 20 is firmly in contact (e.g., in close contact) with the first surface of the substrate 10.

The insulating member 40 is disposed between the magnet plate 30 and the substrate 10 so that the magnet plate 30 and the substrate 10 are not directly in contact with each other, and thus, the insulating member 40 may prevent the occurrence of a temperature gradient in the substrate 10.

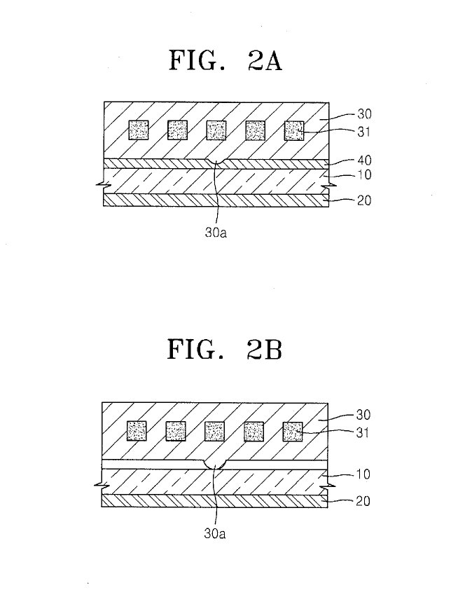

Hereinafter, FIG. 2A and FIG. 2B will be compared and described.

FIG. 2A illustrates a structure in which the insulating member 40 is disposed between the magnet plate 30 and the substrate 10, such as a structure of the embodiment illustrated in FIG. 1, and FIG. 2B illustrates a structure having no insulating member 40 as a comparative example.

First, in a case where there is no insulating member 40, as in the structure illustrated in FIG. 2B, a roughness protrusion 30a formed on a surface of the magnet plate 30 is in contact (e.g., close contact or direct contact) with the substrate 10, causing the substrate 10 to be in a state of partial point contact with the magnet plate 30. Because the magnet plate 30 is generally formed of a metallic material having relatively high thermal conductivity, a temperature of the substrate 10 at a portion being in point contact with the magnet plate 30 is relatively lower than that of the substrate 10 at other portions. As a result, a phenomenon (e.g., so-called “thermo-capillary convection effect”) occurs, in which a deposit in an unsolidified state (e.g., a liquid phase or state) accumulates at the portions of the substrate 10 having a lower temperature, and thus, local thick-film defects may occur, in which a thicker film is formed on the corresponding portions of the substrate 10.

However, in a case where the insulating member 40 is disposed between the magnet plate 30 and the substrate 10, a local temperature gradient is reduced or prevented in the substrate 10, such as in the embodiment illustrated in FIG. 2A, because the magnet plate 30 having relatively high thermal conductivity is not in contact (e.g., directly in contact) with the substrate 10. That is, because the surface (e.g., the entire surface) of the magnet plate 30 including the protrusion 30a that faces the substrate 10 is covered by (e.g., entirely covered by) the insulating member 40, only the insulating member 40 is directly in contact with the second surface of the substrate 10. Even in a case where fine protrusions may be included on the surface of the insulating member 40, the formation of the temperature gradient due to the magnet plate 30 may be prevented or may be reduced because thermal conductivity of the insulating member 40 is relatively low.

Therefore, the phenomenon in which local thick-film defects occur due to the temperature gradient may be reduced or prevented. Thus, a uniform thin film may be formed.

A fluororesin, such as Teflon®, or polyether ether ketone may be included in (e.g., used as) the insulating member 40.

The thin film deposition apparatus having the above-described configuration may be operated as follows.

A method for depositing an organic layer for thin film encapsulation of an organic light-emitting display apparatus may include preparing the substrate 10 of the organic light-emitting display apparatus for forming the organic layer, and installing the substrate 10 in the chamber 60 after the mask 20 is disposed on the first surface of the substrate 10 and the magnet plate 30 having the insulating member 40 disposed thereon is disposed on the second surface of the substrate 10.

Thereafter, the deposition source 50 configured to inject the deposition gas to form the organic layer is prepared and the deposition is initiated. The organic layer for thin film encapsulation is formed while the organic layer deposition gas is deposited on the substrate 10 through the openings 21 of the mask 20.

In this case, the magnet plate 30 pulls the mask 20 to be firmly in contact (e.g., in close contact) with the first surface of the substrate 10 by magnetic force of the magnets 31, wherein the insulating member 40 reduces or prevents the phenomenon in which the local temperature gradient in the substrate 10 is formed due to the contact (e.g., direct contact) between the magnet plate 30 and the substrate 10.

Therefore, the local thick-film defects may not occur, and thus, a uniform and clean organic layer of the thin film encapsulation of the organic light-emitting display apparatus may be formed.

When the thin film deposition apparatus having the above configuration is used, the local thick-film defects may be reduced or prevented. Thus, a failure rate of the product may be decreased and production efficiency may be increased when the above-described thin film deposition apparatus is used.

The thin film encapsulation layer of the organic light-emitting display apparatus may protect a display unit on the substrate from external oxygen or moisture by covering the display unit, and the thin film encapsulation layer may have a multilayer structure in which one or more inorganic layers and one or more organic layers are stacked (e.g., alternatingly stacked).

For example, the inorganic layer may include any one of silicon nitride (e.g., SiNₓ), aluminum oxide (e.g., Al₂O₃), silicon oxide (e.g., SiO₂), or titanium oxide (e.g., TiO₂). An uppermost layer of the thin film encapsulation layer that is exposed to the outside may be formed of an inorganic layer in order to reduce or prevent the penetration of moisture into the display unit. The thin film encapsulation layer may include at least one sandwich structure, in which at least one organic layer is between at least two inorganic layers. Also, the thin film encapsulation layer may include at least one sandwich structure, in which at least one inorganic layer is between at least two organic layers. The thin film encapsulation layer may include (e.g., sequentially include) a first inorganic layer, a first organic layer, and a second inorganic layer from a top of the display unit. Also, the thin film encapsulation layer may include (e.g., sequentially include) a first inorganic layer, a first organic layer, a second inorganic layer, a second organic layer, and a third inorganic layer from the top of the display unit. The thin film encapsulation layer may include (e.g., sequentially include) a first inorganic layer, a first organic layer, a second inorganic layer, a second organic layer, a third inorganic layer, a third organic layer, and a fourth inorganic layer from the top of the display unit. A metal halide layer, including, for example, lithium fluoride (LiF), may be further included between the display unit and the first inorganic layer. The metal halide layer may protect the display unit from damage caused when the first inorganic layer is formed by sputtering or plasma deposition. The first organic layer may have an area (e.g., a surface area) that is smaller than that of the second inorganic layer, and the second organic layer may also have an area (e.g., a surface area) that is smaller than that of the third inorganic layer. Also, the first organic layer may be covered (e.g., completely covered) by the second inorganic layer, and the second organic layer may also be covered (e.g., completely covered) by the third inorganic layer.

The organic layer may be formed of a polymer, and may be formed of any one of a polyethylene terephthalate, a polyimide, a polycarbonate, an epoxy, a polyethylene, and a polyacrylate. For example, the organic layer may be formed of a polyacrylate and for example, may include a polymerized monomer composition including a diacrylate-based monomer and/or a triacrylate-based monomer. A monoacrylate-based monomer may be further included in the monomer composition. Also, a known photoinitiator, such as a thermoplastic olefin (TPO) (e.g., 2,4,6-trimethylbenzoyl-diphenyl-phosphineoxide), may be further included in the monomer composition. However, the organic layer is not limited thereto.

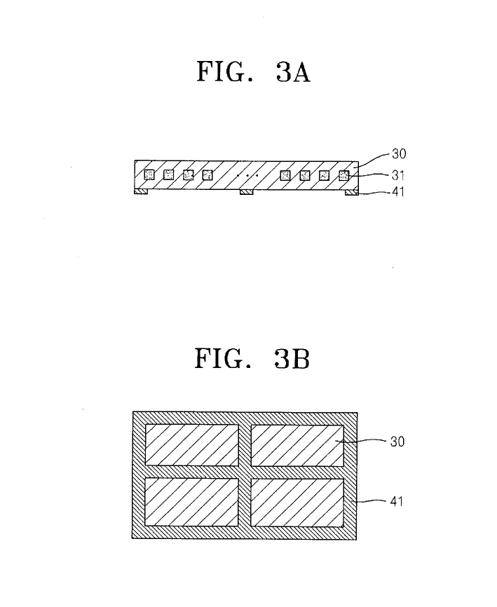

Although the above-described embodiment provides an example of the structure in which the insulating member 40 covers the entire surface of the magnet plate 30 facing the substrate 10, a structure as illustrated in FIGS. 3A and 3B may be configured in which only a portion of the surface of the magnet plate 30 is covered with an insulating member 41 having a grid shape.

Even in this case, because the magnet plate 30 and the substrate 10 are not directly in contact with each other due to a thickness of the insulating member 41, the local thick-film defects may be reduced or prevented. Therefore, as illustrated in this embodiment, the insulating member 41 may be modified into various shapes.

When the above-described thin film deposition apparatus and thin film deposition method are used, the occurrence of the local thick-film defects due to the temperature gradient may be effectively reduced or prevented during the deposition process. Thus, the failure rate of the product may be decreased and the production efficiency may be increased when the thin film deposition apparatus and the thin film deposition method as described above are used.

It should be understood that the embodiments described herein should be considered in a descriptive sense only and not for purposes of limitation. Descriptions of features and/or aspects within each embodiment should typically be considered as available for other similar features or aspects in other embodiments.

While one or more embodiments of the present invention have been described with reference to the included figures, it will be understood by those of ordinary skill in the art that various changes in form and details may be made therein without departing from the spirit and scope of the present invention as defined by the following claims and their equivalents.

What is claimed is:

1. A thin film deposition apparatus comprising:
a mask in contact with a first surface of a substrate;
a magnet plate above a second surface of the substrate and configured to pull the mask toward the first surface of the substrate, the second surface of the substrate being an opposite surface to the first surface; and
an insulating member between the magnet plate and the second surface of the substrate.

2. The thin film deposition apparatus of claim 1, wherein the insulating member comprises a fluororesin or polyether ether ketone.

3. The thin film deposition apparatus of claim 1, wherein the insulating member covers an entire surface of the magnet plate that faces the second surface of the substrate.

4. The thin film deposition apparatus of claim 1, wherein the insulating member covers a portion of the surface of the magnet plate that faces the second surface of the substrate.

5. The thin film deposition apparatus of claim 4, wherein the insulating member has a grid shape.

6. The thin film deposition apparatus of claim 1, wherein the magnet plate comprises a plurality of magnets surrounded by a filler.

7. The thin film deposition apparatus of claim 6, wherein the magnets in the magnet plate are arranged as a grid.

8. The thin film deposition apparatus of claim 6, wherein the magnets in the magnet plate are arranged in a repeating pattern.

9. A method of depositing a thin film, the method comprising:
preparing a substrate in a chamber, a mask that is in contact with a first surface of the substrate, and a magnet plate on an insulating member that is on a second surface of the substrate opposite to the first surface; and
operating a deposition source prepared in the chamber to form a thin film on the first surface of the substrate through the mask.

10. The method of claim 9, wherein the thin film formed on the first surface of the substrate comprises an organic layer for thin film encapsulation of an organic light-emitting display apparatus.

11. The method of claim 9, wherein the insulating member comprises of a fluororesin or polyether ether ketone.

12. The method of claim 9, wherein the insulating member covers an entire surface of the magnet plate that faces the second surface of the substrate.

13. The method of claim 9, wherein the insulating member covers a portion of the surface of the magnet plate that faces the second surface of the substrate.

14. The method of claim 13, wherein the insulating member has a grid shape.
